(19) United States
(12) Patent Application Publication
(10) Pub. No.: US 2022/0052128 A1
(43) Pub. Date: Feb. 17, 2022

(54) DISPLAY DEVICE

(71) Applicant: SHARP KABUSHIKI KAISHA, Sakai City, Osaka (JP)

(72) Inventors: MASAFUMI UENO, Sakai City, Osaka (JP); MASAAKI MORIYA, Sakai City, Osaka (JP); NAOKI SHIOBARA, Sakai City, Osaka (JP)

(21) Appl. No.: 17/274,777

(22) PCT Filed: Sep. 10, 2018
(86) PCT No.: PCT/JP2018/033449

§ 371 Date: Mar. 9, 2021

(51) Int. Cl. H01L 27/32; H01L 51/52

(52) U.S. Cl. CPC H01L 27/3232; H01L 51/5271

(57) ABSTRACT

A display device includes a display panel provided with a display region including a plurality of self light-emitting elements, a light-transmitting protective member that covers a surface of the display panel, a housing that houses the display panel and the protective member, and a luminance sensor provided so as not to overlap with the display region. A portion of light from the self light-emitting element positioned inside the display region and adjacent to the luminance sensor is guided to the luminance sensor.

### TECHNICAL FIELD

The present invention relates to a display device.

### BACKGROUND ART

In PTL 1, a technique is disclosed in which, by providing a luminance sensor unit including dummy pixels outside a pixel unit (a display region) including a plurality of self light-emitting elements, degradation over time of the self light-emitting elements in the pixel unit is compensated for based on a detection result from the luminance sensor unit.

### CITATION LIST

### Patent Literature

PTL 1: JP 2010-243895 A (published on Oct. 28, 2010)

### SUMMARY OF INVENTION

### Technical Problem

In the above-described technique, in addition to the need to provide the dummy pixels in a non-display region, there is a problem in that accuracy of the compensation is low because the dummy pixels are provided in the non-display region.

### Solution to Problem

A display device according to an aspect of the present invention includes a display panel provided with a display region including a plurality of self light-emitting elements, a light-transmitting protective member configured to cover a surface of the display panel, a housing configured to house the display panel and the protective member, and a luminance sensor provided not to overlap with the display region. Light from the self light-emitting element positioned inside the display region and adjacent to the luminance sensor is guided to the luminance sensor.

### Advantageous Effects of Invention

According to an aspect of the present invention, accuracy of luminance compensation can be improved.

### BRIEF DESCRIPTION OF DRAWINGS

FIG. 1(a) is a cross-sectional view illustrating a configuration example of a display panel, and FIG. 1(b) is a circuit diagram illustrating an example of a control circuit of a light-emitting element.

FIG. 2(a) is a plan view of a display device according to a first embodiment, and FIGS. 2(b) to 2(d) are cross-sectional views of the display device illustrated in FIG. 2(a).

FIG. 3 is a block diagram illustrating a configuration of the display device.

FIG. 4(a) is a plan view of the display device according to a second embodiment, and FIGS. 4(b) to 4(d) are cross-sectional views of the display device illustrated in FIG. 4(a).

FIG. 5(a) is a plan view of the display device according to a third embodiment, and FIGS. 5(b) and 5(c) are cross-sectional views of the display device illustrated in FIG. 5(a).

FIG. 6(a) is a plan view of the display device according to a fourth embodiment, and FIGS. 6(b) and 6(c) are cross-sectional views of the display device illustrated in FIG. 6(a).

FIG. 7(a) is a plan view of the display device according to a fifth embodiment, and FIGS. 7(b) to (c) are cross-sectional views of the display device illustrated in FIG. 7(a).

FIGS. 8(a) to 8(c) are cross-sectional views of the display device according to a sixth embodiment.

FIGS. 9(a) and 9(b) are cross-sectional views of the display device according to a sixth embodiment.

### DESCRIPTION OF EMBODIMENTS

Hereinafter, “the same layer” means that the layer is formed in the same process (film formation process), “a lower layer” means that the layer is formed in an earlier process than the process in which the layer to compare is formed, and “an upper layer” means that the layer is formed in a later process than the process in which the layer to compare is formed.

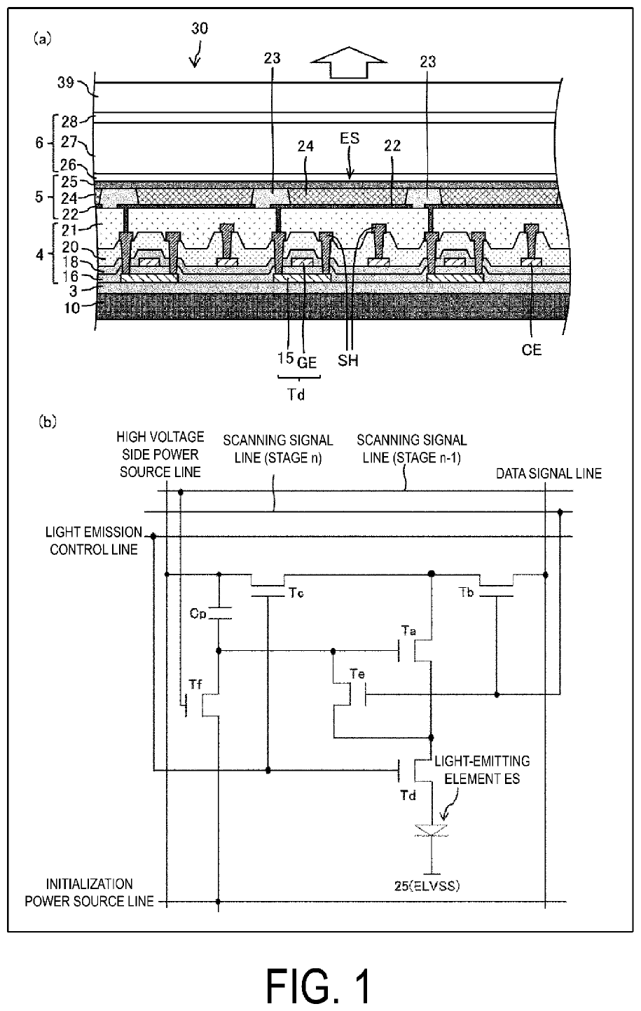

FIG. 1(a) is a cross-sectional view illustrating a configuration example of a display panel, and FIG. 1(b) is a circuit diagram illustrating an example of a control circuit of a light-emitting element.

A display panel 30 includes a barrier layer 3, a TFT layer 4, a light-emitting element layer 5, a sealing layer 6, and a function layer 39 layered on a substrate 10. The substrate 10 may be a glass substrate or a flexible resin substrate. The barrier layer 3 is a layer that inhibits foreign matter such as water, oxygen, and a mobile ion from penetrating the TFT layer 4 and the light-emitting element layer 5, and can be configured by a silicon oxide film, a silicon nitride film, or a silicon oxynitride film, or by a layered film of these, formed by chemical vapor deposition (CVD).

The TFT layer 4 includes a semiconductor layer 15, inorganic insulating flints 16, 18, and 20, a first metal layer, a second metal layer, a third metal layer, and a flattening film 21. The TFT layer 15 can be formed of, for example, low temperature polysilicon (LTPS) or an oxide semiconductor (an In—Ga—Zn—O based semiconductor, for example). The first metal layer, the second metal layer, and the third metal layer are each formed, for example, of a single-layer or multi-layered film of metal, the metal including at least one of aluminum, tungsten, molybdenum, tantalum, chromium, titanium, and copper. The semiconductor layer 15 includes a channel of a transistor Id, the first metal layer includes a gate electrode GE of the transistor Td, the second metal layer includes a capacitance electrode CE, and the third metal layer includes a source wiring line SH. The flattening film 21 can be formed of, for example, a coatable organic material such as polyimide or acrylic resin.

The light-emitting element layer 5 includes an anode 22, an edge cover 23 covering an edge of the anode 22, an electroluminescent (EL) layer 24, and a cathode 25 in an upper layer overlying the EL layer 24. The edge cover 23 can be formed of a coatable organic material such as polyimide or acrylic resin, for example.

In a display region, a plurality of self light-emitting elements ES (organic light-emitting diodes (OLEDs) or quantum dot light-emitting diodes (QLEDs), for example) are provided, each of which includes the anode 22, the EL layer 24, and the cathode 25. For example, as illustrated in FIG. 1(b), the light-emitting element ES can be controlled by scanning signal lines, a data signal line, a light emission control line, a high-voltage side power source line, an initialization power source line, transistors Ta to If, and a capacitor Cp, which are all provided in the TFT layer 4. A gray scale signal is supplied to the data signal line from a source driver (not illustrated), and a current having a magnitude corresponding to the gray scale signal flows to the light-emitting element ES.

For example, the EL layer 24 is formed by layering a hole injection layer, a hole transport layer, a light-emitting layer, an electron transport layer, and an electron injection layer in this order, from the lower layer side. The light-emitting layer is formed into an island shape so as to overlap with an opening of the edge cover 23 by vapor deposition or an ink-jet method. Other layers are formed in an island shape or a solid-like shape (common layer). A configuration is also possible in which one or more layers are not formed among the hole injection layer, the hole transport layer, the electron transport layer, and the electron injection layer.

When the light-emitting layer of the OLED is formed by vapor deposition, a fine metal mask (FMM) is used. The FMM is a sheet with a large number of through-holes (made of Invar material, for example), and an island-shaped light-emitting layer (corresponding to the single light-emitting element) is formed by an organic material passing through one of the through-holes.

In the case of the light-emitting layer of the QLED, for example, the island-shaped light-emitting layer (corresponding to the single light-emitting element) can be formed by ink-jet coating a solvent having quantum dots diffused therein, or by patterning a solidly coated quantum dot layer using a photolithography method.

The anode (anode electrode) 22 is formed by a layering of indium tin oxide (ITO) and silver (Ag) or an alloy containing Ag, for example, and has light reflectivity, The cathode (cathode electrode) 25 can be formed by a transparent conductive material such. as a MgAg alloy (extremely thin film), ITO, or IZO (indium zinc oxide).

When the light-emitting element ES is an OLED, positive holes and electrons recombine inside the light-emitting layer in response to a drive current between the anode 22 and the cathode 25, and light is emitted when the excitons generated in this manner transition to a ground state. Because the cathode 25 is transparent and the anode 22 has light reflectivity, the light emitted from the EL layer 24 travels upward and becomes top-emitting.

When the light-emitting element ES is a QLED, positive holes and electrons recombine inside the light-emitting layer in response to a drive current between the anode 22 and the cathode 25, and light (fluorescence) is emitted when the excitons generated in this manner transition from the conduction band of the quantum dot to the valence band.

A light-emitting element (such as an inorganic light-emitting diode) than an OLED or QLED may be formed in the light-emitting element layer 5.

The sealing layer 6 is transparent, and includes an inorganic sealing film 26 for covering the cathode 25, an organic buffer film 27 formed as an upper layer overlying inorganic sealing film 26, and an inorganic sealing film 28 formed as an upper layer overlying the organic buffer film 27, The sealing layer 6 covering the light-emitting element layer 5 inhibits foreign matter such as water, oxygen, and mobile ions from penetrating the light-emitting element layer 5.

Each of the inorganic sealing film 26 and the inorganic sealing film 28 is an inorganic insulating film and can be formed of, for example, a silicon oxide film, a silicon nitride film, or a silicon oxynitride film, or a layered film of these, formed by CVD. The organic buffer film 27 is a transparent organic film having a flattening effect and can be formed of a coatable organic material such as acrylic resin, The organic buffer film 27 can be formed by ink-jet coating, for example.

The function film 39 includes at least one of an optical compensation function and a touch sensor function, for example.

### First Embodiment

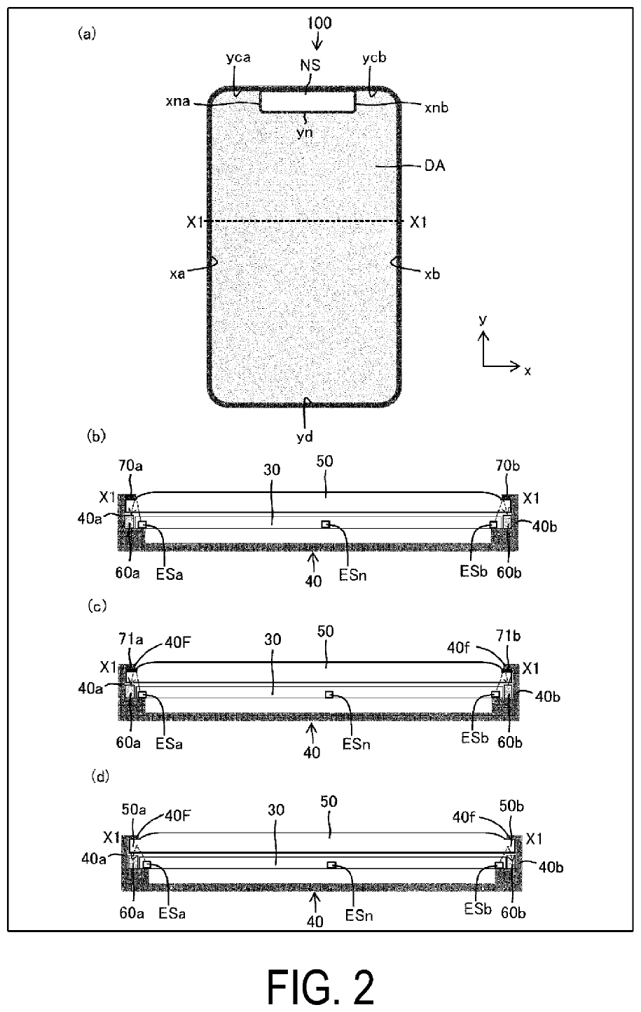

FIG. 2(a) is a plan view of a display device according to a first embodiment, and FIGS. 2(b) to 2(d) are cross-sectional views of the display device illustrated in FIG. 2(a).

A display device 100 includes the display panel 30 provided with a display region DA including the plurality of light-emitting elements, a transparent protective member 50 covering a surface of the display panel 30, a housing 40 housing the display panel 30 and the protective member 50, and luminance sensors 60a and 60b provided so as not to overlap with the display region DA. A portion of light from a light-emitting element ESa (contributing to display) (an OLED or a QLED, which is a self light-emitting element) adjacent to the luminance sensor 60a and positioned in the display region DA is guided to the luminance sensor 60a, and a portion of light from a light-emitting element ESb (contributing to display) (an OLED or a QLED, which is a self light-emitting element, for example) adjacent to the luminance sensor 60b and positioned in the display region DA is guided to the luminance sensor 60b.

The display panel 30 has a rectangular shape having a notch portion NS formed in an upper end portion thereof, and the display region DA includes edges xa and xb along a longitudinal direction (a y direction) and edges yca, ycb, and yd along an x direction (a direction orthogonal to the y direction). The edges yca and ycb are located on both sides of the notch portion NS and face the edge yd. The display region DA includes edges xna, xnb, and yn corresponding to the notch portion NS, and the edge yn along the x direction is longer than each of the edges xna and xnb facing each other in the x direction.

As illustrated in FIGS. 2(a) and 2(b), the housing 40 includes side walls 40a and 40b facing each other in the x direction, a claw-shaped reflective member that 70a protrudes inward from the upper end of the side wall 40a, and a claw-shaped reflective member 70b that protrudes inward from the upper end of the side wall 40b. The reflective member 70a covers a first end portion (an end portion on the left side in the drawing) along they direction of the protective member 50, and the reflective member 70b covers a second end portion (an end portion on the right side in the drawing) along the y direction of the protective member 50. The luminance sensor 60a is provided between the side wall 40a and the display panel 30, and the luminance sensor 60b is provided between the side wall 40b and the display panel 30. The reflective members 70a and 70b preferably have specular reflection (total reflection) properties.

A portion of the light that is emitted from the light-emitting element ESa (at the outermost periphery of the display region DA) adjacent to the inner side of the edge xa of the display region DA and that is transmitted through the protective member 50 is reflected by the reflective member 70a and is incident on the luminance sensor 60a. A portion of the light that is emitted from the light-emitting element ESb (at the outermost periphery of the display region DA) adjacent to the inner side of the edge xb of the display region DA and that is transmitted through the protective member 50 is reflected by the reflective member 70b and is incident on the luminance sensor 60b.

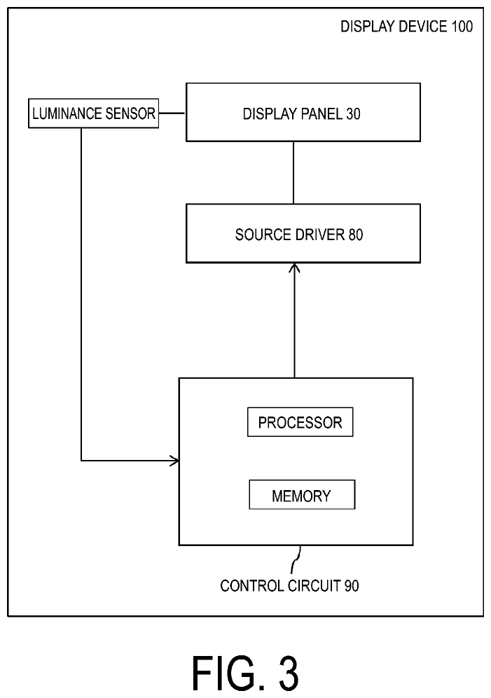

FIG. 3 is a block diagram illustrating a configuration of the display device. As illustrated in FIG. 3, the display device 100 is provided with a source driver 80 that drives the display panel 30, and a control circuit 90 including a processor and a memory.

The control circuit 90 performs characteristic compensation of the light-emitting elements ESa and ESb based on measurement results from the luminance sensors 60a and 60b, electrical characteristics (a current between the anode and the cathode with respect to the gray scale signal, for example) of each of the light-emitting elements ESa and ESb, a set value for the electrical characteristics of each luminescent color, and a set value for light-emission efficiency (a ratio of luminance with respect to the current between the anode and the cathode) of each of the luminescent colors. At least one of a deviation from the set value for the electrical characteristics and a deviation from the set value for the light-emission efficiency, both of which arise from manufacturing variations, degradation over time, and the like, is compensated for by the characteristic compensation.

At least one of the electrical characteristics and light-emission characteristics of the light-emitting element, such as the OLED, may change depending on the ambient temperature. For example, when luminance exceeding a desired luminance with respect to the gray scale signal is measured due to a rise in the ambient temperature, the current between the anode and cathode is corrected to be smaller by the characteristic compensation of the control circuit 90, and as a result, proper display and power saving are achieved.

Furthermore, even for another light-emitting element ESn in the display region, for which the luminance measurement is not performed, the characteristic compensation is performed based on the electrical characteristics of the light-emitting element ESn, and the light-emission efficiency of the light-emitting element ESn, which is estimated from the light-emission efficiency of each of the light-emitting elements ESa and ESb, When the light-emitting elements ESa and ESb emit different luminescent colors, the light-emission efficiency of the light-emitting element ESn is estimated using the light-emission efficiency of the light-emitting element (ESa or ESb) whose luminescent color is the same as that of the light-emitting element ESn.

Specifically, the control circuit 90 calculates, for each of the light-emitting elements, a compensation amount for each of the electrical characteristics and the light-emission efficiency, and outputs, to the source driver 80, a correction signal corresponding to the compensation amount. As a result, the gray scale signal supplied from the source driver 80 to the data signal line is corrected. Note that only the compensation for the light-emission efficiency may be performed.

In the configuration illustrated in FIGS. 2(a) and 2(b), since a portion of the light from each of the light-emitting elements ESa and ESb (contributing to display) in the display region DA is guided to each of the luminance sensors, respectively, it is possible to reduce the size of a frame (the non-display region) and improve the compensation accuracy.

When the measurement results from the luminance sensors 60a and 60b include an influence of external light, the influence of the external light can be eliminated by subtracting a luminance obtained in a state in which the light-emitting elements ESa and ESb are turned off from a luminance obtained in a state in which the light-emitting elements ESa and ESb are illuminated.

Further, since a difference between the luminance obtained in the state in which the light-emitting elements ESa and ESb are illuminated and the luminance (illuminance of the external light) obtained in the state in which the light-emitting elements ESa and ESb are turned off can be calculated, for example, when the illuminance of the external light is larger, viewability is improved by making a correction to increase the current between the anode and the cathode in order to increase the luminance, and when the illuminance of the external light is smaller, power saving can be achieved by making a correction to reduce the current between the anode and the cathode in order to reduce the luminance.

In the first embodiment, as illustrated in FIG. 2(c), the reflective member 71a may be provided on a lower surface (a surface facing the protective member 50) of a claw portion 40F protruding inward from the upper end of the side wall 40a of the housing, and the reflective member 71b may be provided on a lower surface (a surface facing the protective member 50) of a claw portion 40f protruding inward from the upper end of the side wall 4011 of the housing. Further, the reflective member 71a may be provided on an upper surface (a surface facing the claw portion 40F) of the first end portion along the y direction of the protective member 50, and the reflective member 71b may be provided on an upper surface (a surface facing the claw portion 40f) of the second end portion along the y direction of the protective member 50.

In FIG. 2(c), a portion of the light emitted from the light-emitting element ESa and transmitted through the protective member 50 is reflected by the reflective member 71a and is incident on the luminance sensor 60a. Further, a portion of the light emitted from the light-emitting element ESb and transmitted through the protective member 50 is reflected by the reflective member 71b and is incident on the luminance sensor 60b.

Further, in the first embodiment, as illustrated in FIG. 2(d), the first end portion (a portion sandwiched by the claw portion 40F and the luminance sensor 60a) along the y direction of the protective member 50, and the second end portion (a portion sandwiched by the claw portion 40f and the luminance sensor 60b) along the y direction of the protective member 50 may each be provided with a light guiding function.

In FIG. 2(c), a portion of the light emitted from the light-emitting element ESa is guided to the luminance sensor 60a by the first end portion of the protective member 50, Further, a portion of the light emitted from the light-emitting element ESb is guided to the luminance sensor 60b by the second end portion of the protective member 50.

### Second Embodiment

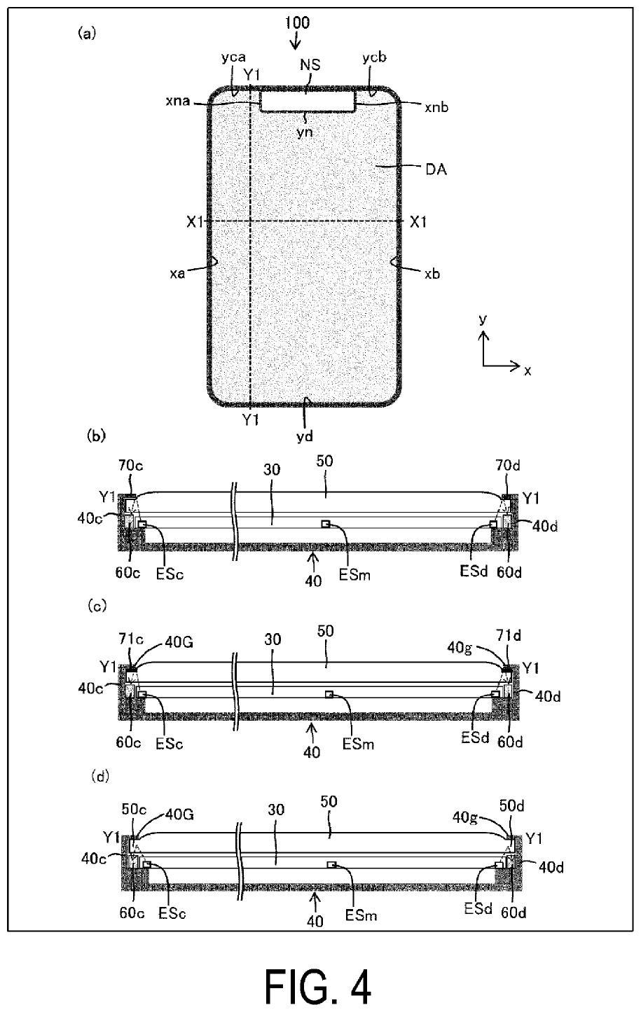

FIG. 4(a) is a plan view of the display device according to a second embodiment, and FIGS. 4(b) to 4(d) are cross-sectional views of the display device illustrated in FIG. 4(a).

As illustrated in FIGS. 4(a) and 4(b), the housing 40 includes side walls 40c and 40d facing each other in the y direction, a claw-shaped reflective member 70c that protrudes inward from the upper end of the side wall 40c, and a claw-shaped reflective member 70d that protrudes inward from the upper end of the side wall 40d. The reflective member 70c covers a first end portion (an upper end portion in the drawing) along the x direction of the protective member 50, and the reflective member 70b covers a second end portion (a lower end portion in the drawing) along the x direction of the protective member 50. A luminance sensor 60c is provided between the side wall 40c and the display panel 30, and a luminance sensor 60d is provided between the side wall 40d and the display panel 30.

A portion of the light that is emitted from a light-emitting element ESc (at the outermost periphery of the display region DA) adjacent to the inner side of the edge yea of the display region DA and that is transmitted through the protective member 50 is reflected by the reflective member 70c and is incident on the luminance sensor 60c. A portion of the light that is emitted from a light-emitting element ESd (at the outermost periphery of the display region DA) adjacent to the inner side of the edge yd of the display region DA and that is transmitted through the protective member 50 is reflected by the reflective member 70d and is incident on the luminance sensor 60d.

The control circuit 90 performs the characteristic compensation of the light-emitting elements ESc and ESd based on measurement results from the luminance sensors 60c and 60d, the electrical characteristics (the current between the anode and the cathode with respect to the gray scale signal, for example) of each of the light-emitting elements ESc and ESd, the set value for the electrical characteristics of each of the luminescent colors, and the set value for the light-emission efficiency (the ratio of luminance with respect to the current between the anode and the cathode) of each of the luminescent colors. Furthermore, even for another light-emitting element ESm in the display region, for which the luminance measurement is not performed, the characteristic compensation is performed based on the electrical characteristics of the light-emitting element ESm, and the light-emission efficiency of the light-emitting element ESm, which is estimated from the light-emission efficiency of each of the light-emitting elements ESc and ESd. When the light-emitting elements ESc and ESd emit different luminescent colors, the light-emission efficiency of the light-emitting element ESm is estimated using the light-emission efficiency of the light-emitting element (ESc or ESd) whose luminescent color is the same as that of the light-emitting element ESm.

In the second embodiment, as illustrated in FIG. 4(c), the reflective member 71c may be provided on a lower surface (a surface facing the protective member 50) of a claw portion 40G protruding inward from the upper end of the side wall 40c of the housing, and the reflective member 71d may be provided on a lower surface (a surface facing the protective member 50) of a claw portion 40g protruding inward from the upper end of the side wall 40d of the housing. Further, the reflective member 71c may be provided on an upper surface (a surface facing the claw portion 40G) of the first end portion along the y direction of the protective member 50, and the reflective member 71d may be provided on an upper surface (a surface facing the claw portion 40g) of the second end portion along the y direction of the protective member 50.

In FIG. 4(c), a portion of the light emitted from the light-emitting element ESa and transmitted through the protective member 50 is reflected by the reflective member 71c and is incident on the luminance sensor 60c. Further, a portion of the light emitted from the light-emitting element ESb and transmitted through the protective member 50 is reflected by the reflective member 71d and is incident on the luminance sensor 60d.

Further, in the second embodiment, as illustrated in FIG. 4(d), the first end portion (a portion sandwiched by the claw portion 40G and the luminance sensor 60c) along the y direction of the protective member 50, and the second end portion (a portion sandwiched by the claw portion 40g and the luminance sensor 60d) along the y direction of the protective member 50 may each be provided with the light guiding function.

In FIG. 4(c), a portion of the light emitted from the light-emitting element ESc is guided to the luminance sensor 60c by the first end portion of the protective member 50. Further, a portion of the light emitted from the light-emitting element ESd is guided to the luminance sensor 60d by the second end portion of the protective member 50.

### Third Embodiment

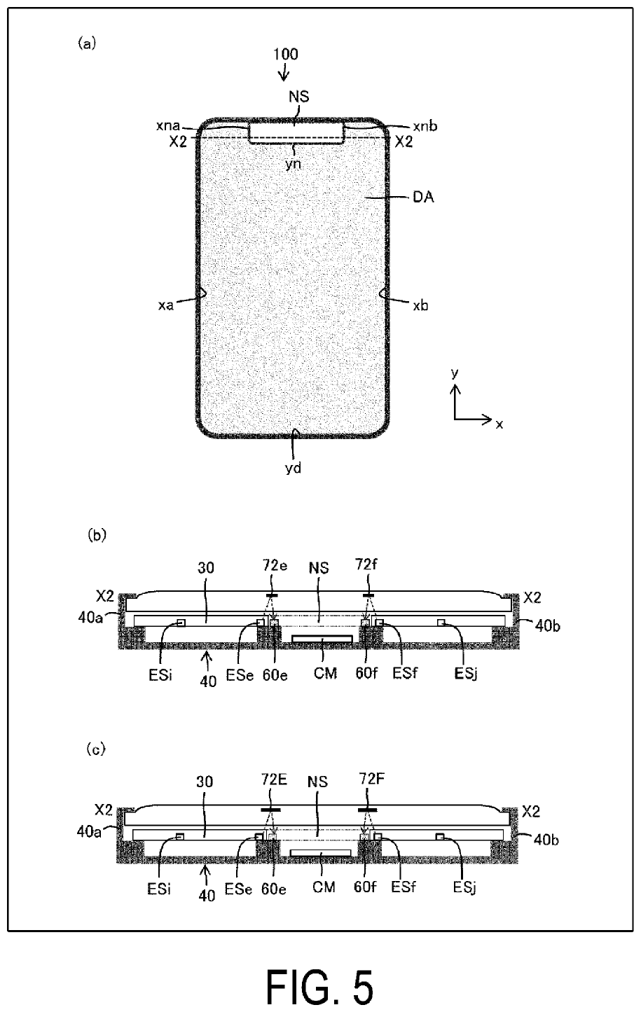

FIG. 5(a) is a plan view of the display device according to a third embodiment, and FIGS. 5(b) and 5(c) are cross-sectional views of the display device illustrated in FIG. 5(a), The display region DA includes the edges xna, xnb, and yn corresponding to the notch portion NS, and the edge yn along the x direction is longer than each of the edges xna and xnb facing each other in the x direction, and is shorter than the edge yd.

As illustrated in FIGS. 5(a) and 5(b), luminance sensors 60e and 60f are provided at both end portions of the notch portion NS of the display panel 30, and a reflective member 72e overlapping with a first end portion of the notch portion NS and a reflective member 72f overlapping with a second end portion of the notch portion NS are provided integrally with the protective member 50. Below the notch portion NS, an imaging element CM is disposed, for example.

A portion of the light that is emitted from the light-emitting element ESe (at the outermost periphery of the display region DA) adjacent to the inner side of the edge xna of the display region DA and that is incident on the protective member 50 is reflected by the reflective member 72e and is incident on the luminance sensor 60e. A portion of the light that is emitted from the light-emitting element ESf (at the outermost periphery of the display region DA) adjacent to the inner side of the edge xnb of the display region DA and that is incident on the protective member 50 is reflected by the reflective member 72f and is incident on the luminance sensor 60f.

The control circuit 90 performs the characteristic compensation of the light-emitting elements ESe and. ESf based on measurement results from the luminance sensors 60e and 60f, the electrical characteristics (the current between the anode and the cathode with respect to the gray scale signal, for example) of each of the light-emitting elements ESe and ESf, the set value for the electrical characteristics of each of the luminescent colors, and the set value for the light-emission efficiency (the ratio of luminance with respect to the current between the anode and the cathode) of each of the luminescent colors. Furthermore, even for other light-emitting elements ESi and ESj in the display region, for which the luminance measurement is not performed, the characteristic compensation is performed based on the electrical characteristics of each of the light-emitting elements ESi and ESj, and the light-emission efficiency of each of the light-emitting elements ESi and ESj, which is estimated from the light-emission efficiency of each of the light-emitting elements ESe and ESf.

In the third embodiment, as illustrated in FIG. 5(c), a reflective member 72E having semi-transparent properties (characteristics that reflect a portion of incident light and transmit the remaining portion of the incident light) may be provided so as to overlap with the first end portion of the notch portion NS and the display region DA, and a reflective member 72F having the semi-transparent properties may be provided so as to overlap with the second end portion of the notch portion NS and the display region DA.

### Fourth Embodiment

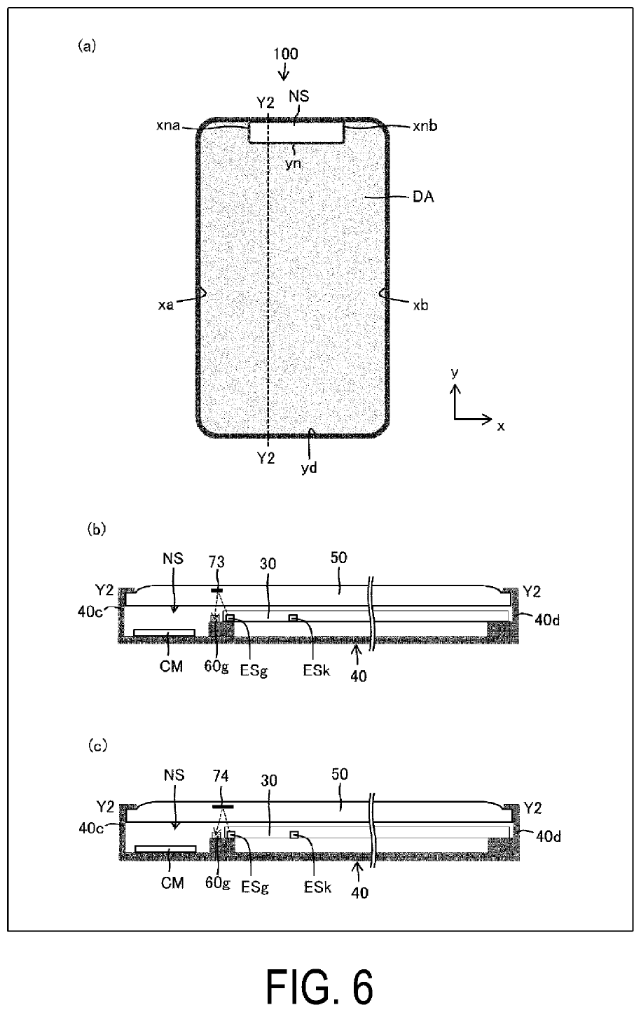

FIG. 6(a) is a plan view of the display device according to a fourth embodiment, and FIGS. 6(b) and 6(c) are cross-sectional views of the display device illustrated in FIG. 6(a). The display region DA includes the edges xna, xnb, and yn corresponding to the notch portion NS, and the edge yn along the x direction is longer than each of the edges xna and xnb facing each other in the x direction, and is shorter than the edge yd.

As illustrated in FIGS. 6(a) and 6(b), a luminance sensor 60g is provided at an end portion on the display region DA side of the notch portion NS, and a reflective member 73 overlapping with the end portion on the display region DA side of the notch portion NS is provided integrally with the protective member 50. Below the notch portion NS, the imaging element CM is disposed, for example.

A portion of the light that is emitted from a light-emitting element ESg (at the outermost periphery of the display region DA) adjacent to the inner side of the edge yn of the display region DA and that is incident on the protective member 50 is reflected by the reflective member 73 and is incident on the luminance sensor 60g.

The control circuit 90 performs the characteristic compensation of the light-emitting element ESg based on a measurement result from the luminance sensor 60g, the electrical characteristics (the current between the anode and the cathode with respect to the gray scale signal, for example) of the light-emitting element ESg, the set value for the electrical characteristics of each of the luminescent colors, and the set value for the light-emission efficiency (the ratio of luminance with respect to the current between the anode and the cathode) of each of the luminescent colors. Furthermore, even for another light-emitting element ESk in the display region, for which the luminance measurement is not performed, the characteristic compensation is performed based on the electrical characteristics of the light-emitting element ESk, and the light-emission efficiency of the light-emitting element ESk, which is estimated from the light-emission efficiency of the light-emitting element ESg.

In the fourth embodiment, as illustrated in FIG. 6(c), a reflective member 74 having the semi-transparent properties (the characteristics that reflect a portion of incident light and transmit the remaining portion of the incident light) may be provided so as to overlap with the first end portion of the notch portion NS and the display region DA.

### Fifth Embodiment

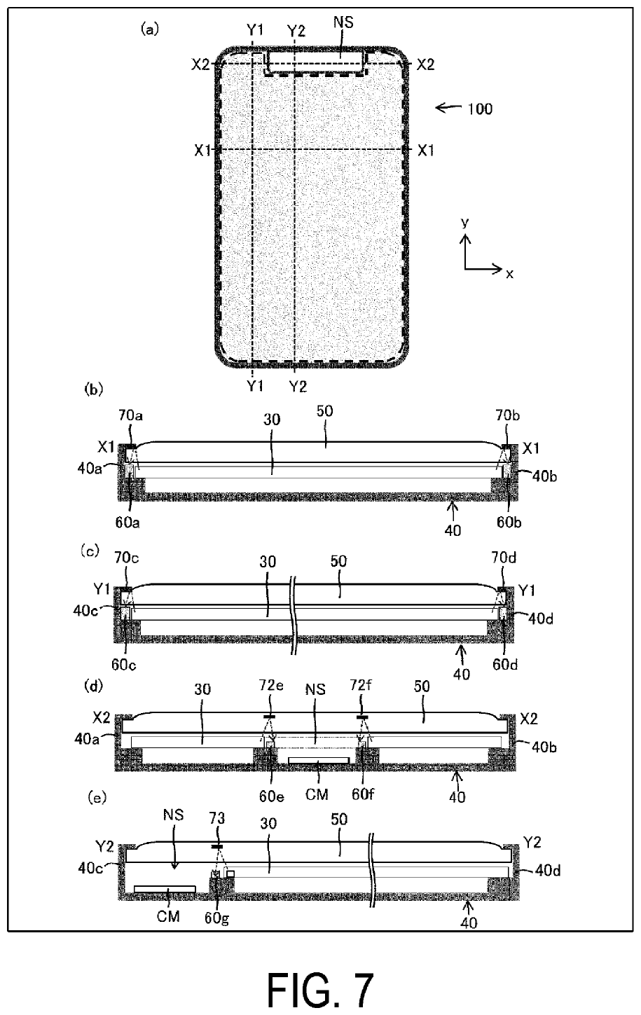

FIG. 7(a) is a plan view of the display device according to a fifth embodiment, and FIGS. 7(b) to 7(e) are cross-sectional views of the display device illustrated in FIG. 7(a).

In the fifth embodiment, by combining the first to fourth embodiments, the luminance sensors 60a to 60g are provided along the entire outer periphery of the display region DA, and the reflective members 70a to 70d, 72e, 72f, and 73 are also provided that respectively reflect a portion of the light from the light-emitting elements at the outermost periphery of the display region DA to the luminance sensors 60a to 60g.

The control circuit 90 performs the characteristic compensation of the light-emitting elements at the outermost periphery of the display region DA based on the measurement results from the luminance sensors 60a to 60g, the electrical characteristics (the current between the anode and the cathode with respect to the gray scale signal, for example) of the light-emitting elements at the outermost periphery of the display region DA, the set value for the electrical characteristics of each of the luminescent colors, and the set value for the light-emission efficiency (the ratio of luminance with respect to the current between the anode and the cathode) of each of the luminescent, colors. Furthermore, even for any chosen light-emitting element in the display region, for which the luminance measurement is not performed, the characteristic compensation is performed based on the electrical characteristics of the chosen light-emitting element, and the light-emission efficiency of the chosen light-emitting element, which is estimated from the light-emission efficiency of the light-emitting elements at the outermost periphery of the display region DA.

### Sixth Embodiment

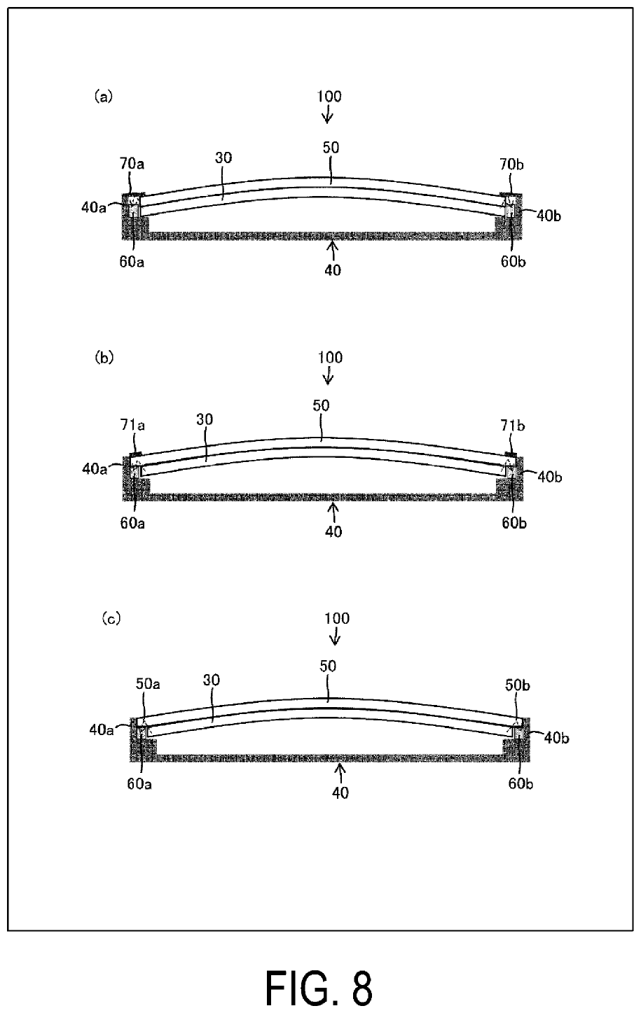

FIGS. 8(a) to 8(c) are cross-sectional views of the display device according to a sixth embodiment. As illustrated in FIG. 8(a), the display panel 30 and the protective member 50 may each have a curved shape that protrudes toward the display surface side, and the reflective member 70a protruding from an upper portion of the side wall 40a and the reflective member 70b protruding from an upper portion of the side wall 40b may each have a curved shape that follows an end portion of the protective member 50.

In the sixth embodiment, as illustrated in FIG. 8(b), the reflective members 71a and 71b may be provided on upper surfaces (each having a curved shape) of both the end portions of the protective member 50, or as illustrated in FIG. 8(c), both end portions 50a and 50b (each having a curved shape) of the protective member 50 may be provided with the light guiding function.

### Seventh Embodiment

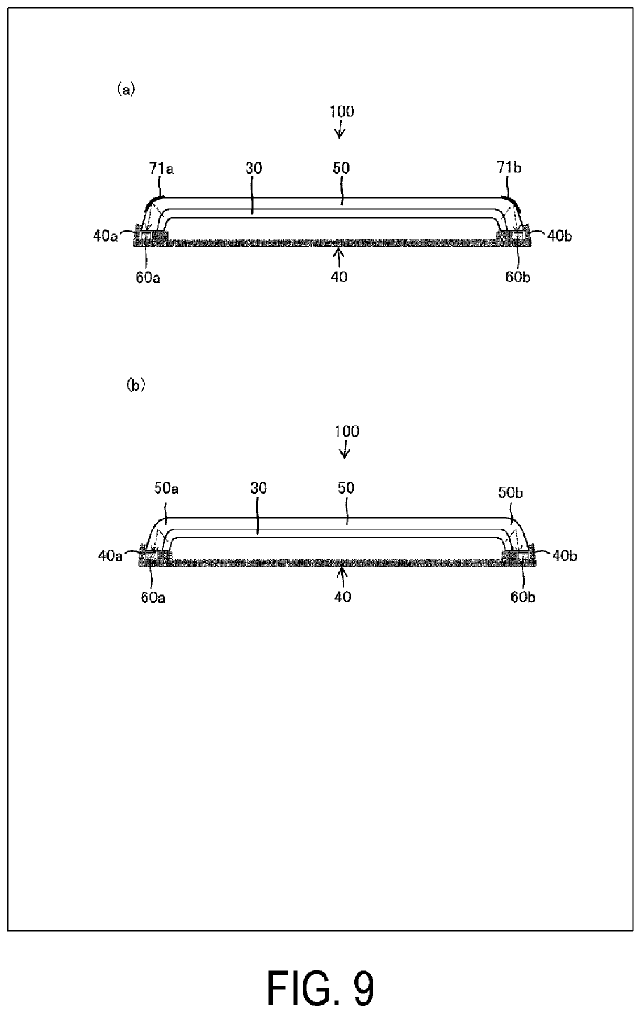

FIGS. 9(a) and 9(b) are cross-sectional views of the display device according to a seventh embodiment. As illustrated in FIG. 9(a), the display panel 30 and the protective member 50 may each have a shape including both end portions each having a curved shape and bent in a perpendicular direction of the display panel, and a flat portion interposed between both the end portions, and the reflective members 71a and 71b may be provided on upper surfaces (each having a curved shape) of both the end portions of the protective member 50. Note that, as illustrated in FIG. 9(b), without providing the reflective members 71a and 71b, both the end portions 50a and 50b of the protective member 50 may each be provided with the light guiding function. In this case, a reflective material and a light diffusing material may be provided on both the end portions 50a and 50b, or, if the light can be guided by light reflection by the curved shape, both the end portions 50a and 50b may have the same configuration as that of the flat portion without providing the reflective material and the light diffusing material on both the end portions 50a and 50b.

### Supplement

### First Aspect

A display device includes a display panel provided with a display region including a plurality of self light-emitting elements, a light-transmitting protective member configured to cover a surface of the display panel, a housing configured to house the display panel and the protective member, and a luminance sensor provided not to overlap with the display region. A portion of light from the self light-emitting element positioned inside the display region and adjacent to the luminance sensor is guided to the luminance sensor.

### Second Aspect

The display device, for example, according to the first aspect includes a reflective member configured to reflect the portion of light from the self light-emitting element adjacent to the luminance sensor toward the luminance sensor.

### Third Aspect

In the display device, for example, according to the second aspect, the luminance sensor is provided between a side wall of the housing and the display panel, and the reflective member is integrally provided with the housing and covers an end portion of the protective member.

### Fourth Aspect

In the display device, for example, according to the second aspect, the reflective member has specular reflection properties.

### Fifth Aspect

In the display device, for example according to the second aspect, a notch portion is formed in a portion of an outer periphery of the display panel, the luminance sensor is provided overlapping with the notch portion, and the reflective member is integrally provided with the protective member and overlaps with the notch portion,

### Sixth Aspect

In the display device, for example, according to the fifth aspect, the reflective member has semi-transparent properties and overlaps with the display region.

### Seventh Aspect

In the display device, for example, according to the first aspect, the display panel and the protective member each have a curved shape protruding toward a display surface side of the display panel.

### Eighth Aspect

In the display device, for example, according to the first aspect, the display panel and the protective member each include an end portion having a curved shape and bent in a direction perpendicular to the display panel.

### Ninth Aspect

In the display device, for example, according to the first aspect, an end portion of the protective member has a light guiding function to guide the portion of light from the self light-emitting element adjacent to the luminance sensor to the luminance sensor.

### Tenth Aspect

The display device, for example, according to the first aspect includes a control circuit including a processor and a memory, and in the display device, the control circuit compensates for light emission efficiency of the self light-emitting element that is a target, based on a measurement result from the luminance sensor.

### Eleventh Aspect

In the display device, for example, according to the tenth aspect, based on respective measurement results obtained when the self light-emitting element adjacent to the luminance sensor is illuminated and turned off, the control circuit compensates for the light emission efficiency of the self light-emitting element that is the target.

### Twelfth Aspect

In the display device, for example, according to the tenth aspect, the control circuit compensates for electrical characteristics of the self light-emitting element that is the target.

### Thirteenth Aspect

In the display device, for example, according to the tenth aspect, the control circuit corrects a deviation, of the self light-emitting element that is the target, from a set value for the light emission efficiency, the deviation arising from at least one of a manufacturing variation, degradation over and an environmental temperature of the self light-emitting element that is the target.

### Fourteenth Aspect

In the display device, for example, according to the twelfth aspect, the control circuit corrects a deviation, of the self light-emitting element that is the target, from a set value for the electrical characteristics, the deviation arising from at least one of a manufacturing variation, degradation over time, and an environmental temperature of the self light-emitting element that is the target.

### Fifteenth Aspect

The display device, for example, according to the first aspect includes a control circuit including a processor and a memory, and in the display device, based on respective measurement results obtained when the self light-emitting element adjacent to the luminance sensor is illuminated and turned off, the control circuit compensates for luminance of the self light-emitting element that is a target.

### REFERENCE SIGNS LIST

100 Display device
30 Display panel
40 Housing
50 Protective member
60a to 60g Luminance sensor
70a to 70d Reflective member
71a to 71d Reflective member
DA Display region
ESa to ESd Light-emitting element (of display region)

1. A display device comprising:
a display panel provided with a display region including a plurality of self light-emitting elements;
a light-transmitting protective member configured to cover a surface of the display panel;
a housing configured to house the display panel and the protective member; and
a luminance sensor provided not to overlap with the display region,
wherein a portion of light from the self light-emitting element positioned inside the display region and adjacent to the luminance sensor is guided to the luminance sensor.

2. The display device according to claim 1, comprising:
a reflective member configured to reflect the portion of light from the self light-emitting element adjacent to the luminance sensor toward the luminance sensor.

3. The display device according to claim 2,
wherein the luminance sensor is provided between a side wall of the housing and the display panel, and
the reflective member is integrally provided with the housing and covers an end portion of the protective member.

4. The display device according to claim 2,
wherein the reflective member has specular reflection properties.

5. The display device according to claim 2,
wherein a notch portion is formed in a portion of an outer periphery of the display panel,
the luminance sensor is provided overlapping with the notch portion, and
the reflective member is integrally provided with the protective member and overlaps with the notch portion.

6. The display device according to claim 5,
wherein the reflective member has semi-transparent properties and overlaps with the display region.

7. The display device according to claim 1,
wherein the display panel and the protective member each have a curved shape protruding toward a display surface side of the display panel.

8. The display device according to claim 1,
wherein the display panel and the protective member each include an end portion having a curved shape and bent in a direction perpendicular to the display panel.

9. The display device according to claim 1,
wherein an end portion of the protective member has a light guiding function to guide the portion of light from the self light-emitting element adjacent to the luminance sensor to the luminance sensor.

10. The display device according to claim 1, comprising:
a control circuit including a processor and a memory,
wherein the control circuit compensates for light emission efficiency of the self light-emitting element that is a target, based on a measurement result from the luminance sensor.

11. The display device according to claim 10,
wherein, based on respective measurement results obtained when the self light-emitting element adjacent to the luminance sensor is illuminated and turned off, the control circuit compensates for the light emission efficiency of the self light-emitting element that is the target.

12. The display device according to claim 10,
wherein the control circuit compensates for electrical characteristics of the self light-emitting element that is the target.

13. The display device according to claim 10,
wherein the control circuit corrects a deviation, of the self light-emitting element that is the target, from a set value for the light emission efficiency, the deviation arising from at least one of a manufacturing variation, degradation over time, and an environmental temperature of the self light-emitting element that is the target.

14. The display device according to claim 12,
wherein the control circuit corrects a deviation, of the light-emitting element that is the target, from a set value for the electrical characteristics, the deviation arising from at least one of a manufacturing variation, degradation over time, and an environmental temperature of the self light-emitting element that is the target.

15. The display device according to claim 1, comprising:
a control circuit including a processor and a memory,
wherein, based on respective measurement results obtained when the self light-emitting element adjacent to the luminance sensor is illuminated and turned off, the control circuit compensates for luminance of the self light-emitting element that is a target.
